(19) United States
(12) Patent Application Publication
(10) Pub. No.: US 2012/0236478 A1
(43) Pub. Date: Sep. 20, 2012

(54) BATTERY COVER ASSEMBLY FOR ELECTRONIC DEVICES

(75) Inventors: ZHENG SHI, Shenzhen City (CN); GUO-WU JIANG, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/240,289

(22) Filed: Sep. 22, 2011

(30) Foreign Application Priority Data
Mar. 14, 2011 (CN) 201110060456.3

(51) Int. Cl. H05K 5/03; B65D 85/00

(52) U.S. Cl. 361/679.01; 206/703

(57) ABSTRACT

A battery cover assembly includes a main body and a battery cover detachably attached to the main body. The main body defines at least one latching portion, at least one opening and a slot adjacent to the at least one opening. The battery cover includes at least one protrusion, at least one extending block and a retaining member adjacent to the at least one extending block. The at least one protrusion is slidably latched with the at least one latching portion. The retaining member passes the slot to latch on the main body. The at least one extending block engages into the at least one opening.

### CROSS-REFERENCE TO RELATED APPLICATIONS

This application is related to co-pending U.S. patent application (Attorney Docket No. US37120), entitled “BATTERY COVER ASSEMBLY FOR ELECTRONIC DEVICES”, by Shi et al. The application has the same assignee as the present application and has been concurrently filed herewith. The above-identified applications are incorporated herein by reference.

### BACKGROUND

1. Technical Field

The present disclosure generally relates to battery cover assemblies and electronic devices using the same.

2. Description of Related Art

Batteries are widely used in electronic devices, such as personal digital assistants, mobile phones, and so on. Generally, batteries are received in the electronic device, and a battery cover is assembled with housing of the electronic device to protect the batteries. When the batteries are damaged and/or dead, the battery cover is opened to replace the batteries. However, a typical battery cover is inconvenient to disassemble from the housing of the electronic device.

Therefore, there is a room for improvement within the art.

### BRIEF DESCRIPTION OF THE DRAWINGS

Many aspects of the present battery cover assemblies and electronic devices using the same can be better understood with reference to the following drawings. The components in the drawings are not necessarily to scale, the emphasis instead being placed upon clearly illustrating the battery cover assemblies and electronic devices using the same. Moreover, in the drawings, like reference numerals designate corresponding parts throughout the several views.

FIG. 1 is an exploded view of a battery cover assembly according to an exemplary embodiment.

FIG. 2 is similar to FIG. 1, but shown from another angle.

FIG. 3 is an enlarged view of a circular area III shown in FIG. 1.

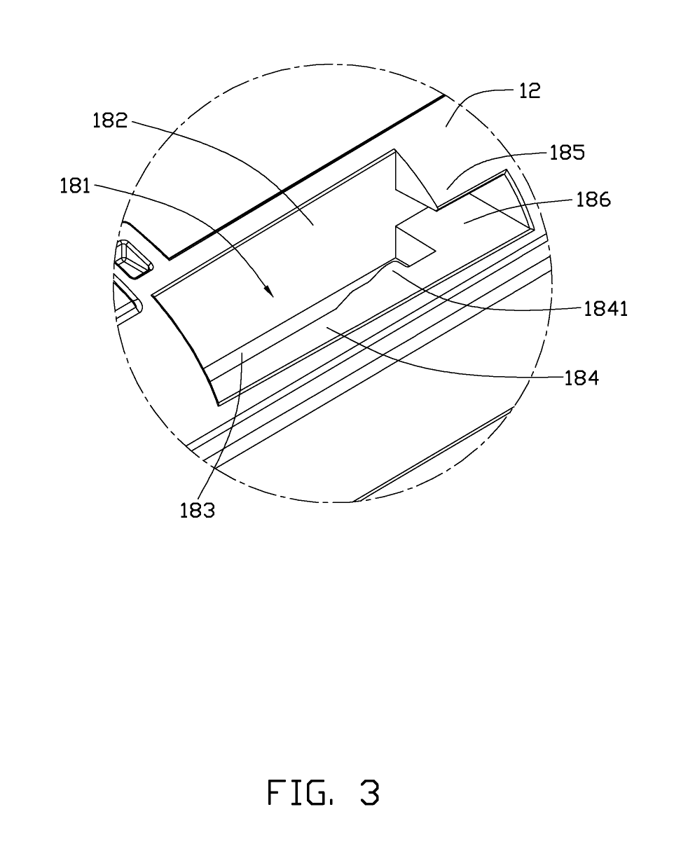

FIG. 4 is a partially assembled view of the battery cover assembly shown in FIG. 1.

### DETAILED DESCRIPTION

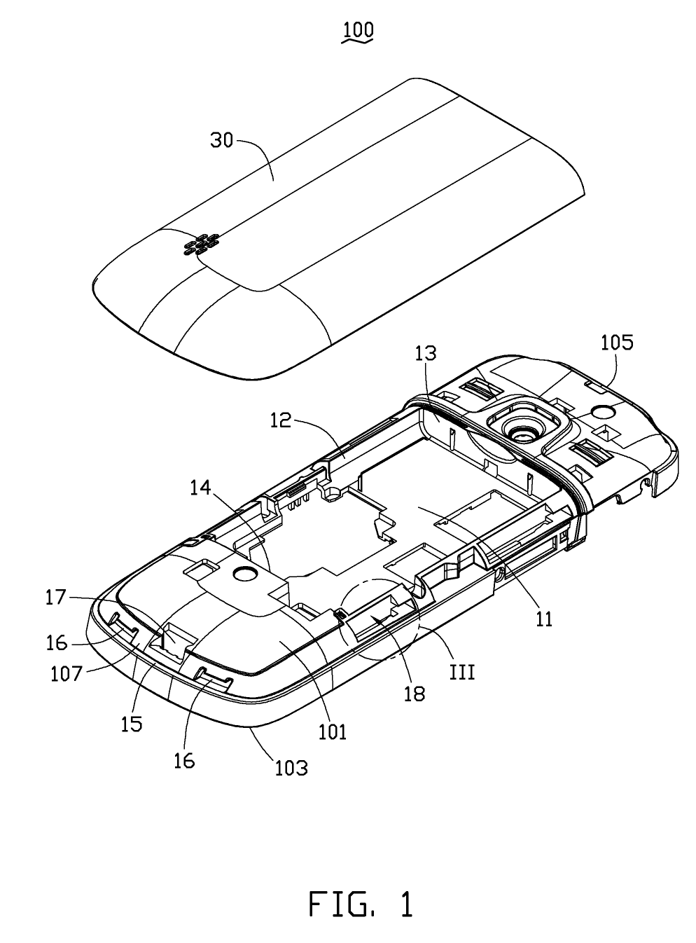

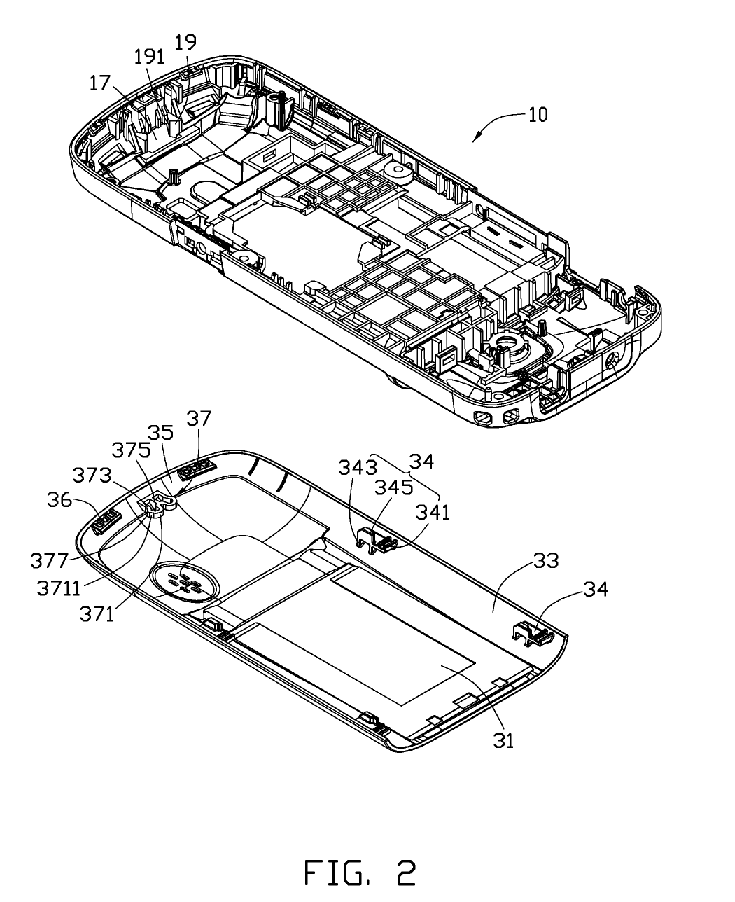

FIGS. 1 and 2 show an electronic device, such as a mobile phone, employing a battery cover assembly 100. The mobile phone is an exemplary application, for the purposes of describing details of an exemplary embodiment of the battery cover assembly 100. The battery cover assembly 100 includes a main body 10 and a battery cover 30 detachably attached to the main body 10.

The main body 10 includes an outer surface 101 and an inner surface 103 opposite to the outer surface 101. The outer surface 101 defines a receiving chamber 11 for receiving a battery of the electronic device. One end of the outer surface 101 includes a first end portion 105, and one opposite end of the outer surface 101 includes a second end portion 107.

The receiving chamber 11 includes two opposite sidewalls 12, a first end wall 13, and a second end wall 14 opposite to the first end wall 13. Each sidewall 12 is connected to the first end wall 13 and the second end wall 14. Peripheral edges of the first end wall 13, the two sidewalls 12, and the second end portion 107 provide a mating surface 15 for engaging with an inner surface of the battery cover 30. The mating surface 15 is lower than the outer surface 101. Two spaced openings 16 and a slot 17 are defined in the second end portion 107, and the slot 17 is located between the two openings 16. Two opposite projections 19 are formed on the inner surface 103, and are spaced from each other by the slot 17. In this exemplary embodiment, each projection 19 is a substantially triangular prism, and defines a chamfer 191 adjacent to the slot 17.

Each sidewall 12 includes two latching portions 18 spaced from each other. Each latching portion 18 defines a notch 181 and has a stopping block 185 positioned at a corner of the notch 181. The notch 181 is surrounded by a first resisting wall 182 and a second resisting wall 184 substantially perpendicular to the first resisting wall 182. The second resisting wall 184 defines a containing slot 183 communicating with the notch 181. A resisting portion 1841 parallelly extends from the second resisting wall 184 and is substantially perpendicularly to the first resisting wall 182. The resisting portion 1841 is made of resilient material such as rubber. A receiving cavity 186 is defined by the stopping block 185 and the second resisting wall 184.

The battery cover 30 includes a main portion 31, two opposite side plates 33 extending from lateral edges of the main portion 31, and an end plate 35 extending from a top edge of the main portion 31 to connect together the two opposite side plates 33. Two spaced protrusions 34 are located on each side plate 33. Each protrusion 34 includes a base portion 341, two support portions 343, and a latching projection 345 substantially perpendicularly protruding from a side of the base portion 341. The base portion 341 is substantially perpendicularly positioned on the side plate 33, and is substantially parallel with the main portion 31. The base portion 341 can slidably engage in the receiving cavity 186. The two support portions 343 are located on the side plate 33 for supporting the base portion 341. Each of the latching projections 345 can slidably engage in the corresponding containing slot 183, respectively.

Two extending blocks 36 and a retaining member 37 are located on the end plate 35. The two extending blocks 36 are spaced from each other by the retaining member 37. Each extending block 36 can engage in the corresponding opening 16. The retaining member 37 is made of resilient material such as rubber, or plastic. The retaining member 37 includes a guiding portion 371, two extending portions 373, and a connecting portion 375. The guiding portion 371 is substantially M-shaped, and each end of the guiding portion 371 includes a guiding surface 3711. Each extending portion 373 extends from one end of the guiding portion 371 and is connected to the end plate 35. A junction 377 is formed between each extending portion 373 and the guiding portion 371 for engaging with the projection 19. The connecting portion 375 extends from a middle of the guiding portion 371 and is connected to the end plate 35. In this exemplary embodiment, the retaining member 37 is integrally formed with the battery cover 30.

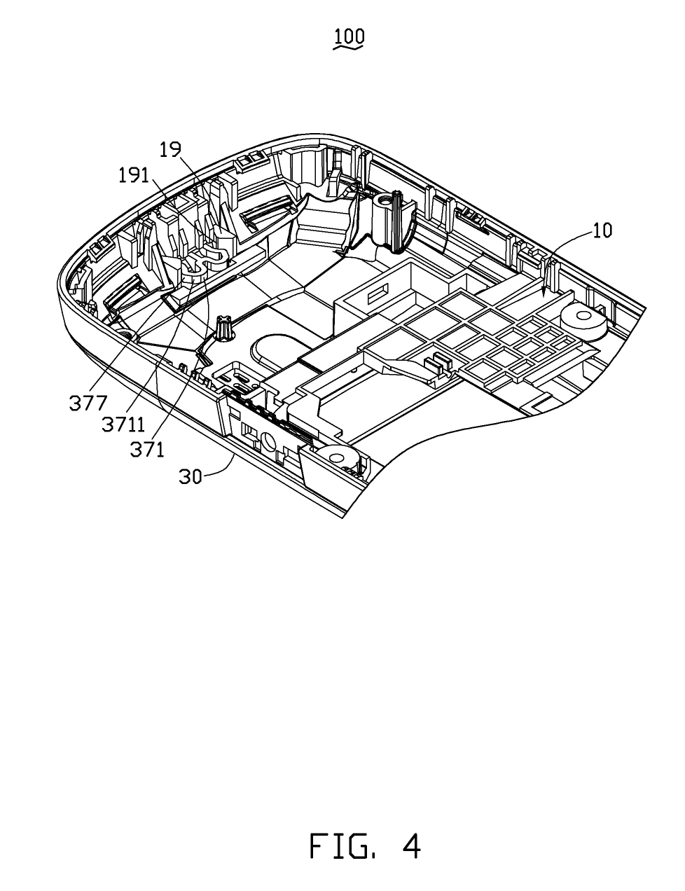

Referring to FIG. 1, FIG. 2 and FIG. 4, the assembly process of the battery cover assembly 100 may be described as follows:

The battery cover 30 abuts against the mating surface 15 of the main body 10. Each latching projection 345 is received in the corresponding containing slot 183. Meanwhile, the extending blocks 36 are aligned with the openings 16, and the retaining member 37 is aligned with the slot 17. The battery cover 30 is pushed towards the first end portion 105 until the latching projection 345 abuts against the resisting portion 1841, and the guiding surface 3711 abuts against the chamfer 191. The battery cover 30 is further pushed towards the first end portion 105, the resisting portion 1841 is deformed to allow the latching projection 345 pass over the resisting portion 1841, and the guiding portion 371 is deformed to allow the projection 19 to pass over the junction 377 along the guiding surface 3711. The projection 19 is blocked between the junction 377 and the extending portion 373. Accordingly, the battery cover 30 is assembled to the main body 10.

The disassembly process of the battery cover assembly 100 may be described as follows: the battery cover 30 is pushed towards the second end portion 107, the resisting portion 1841 is deformed to make the latching projection 345 pass over the resisting portion 1841, and the guiding portion 371 is deformed to urge the projection 19 to pass over the junction 377. The extending block 36 is disassembled from the opening 16. Accordingly, the battery cover 30 is disassembled from the main body 10.

The battery cover 30 can conveniently to assembled and disassembled.

In another exemplary embodiment, there are only one protrusion 34, one extending block 36, one opening 16, and one latching portion 18.

In another exemplary embodiment, the connecting portion 375 may be omitted.

It is to be understood, however, that even through numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A battery cover assembly for an electronic device, the battery cover assembly comprising:
a main body defining at least one latching portion, at least one opening and a slot adjacent to the at least one opening; and
a battery cover detachably attached to the main body, the battery cover comprises at least one protrusion, at least one extending block and a retaining member adjacent to the at least one extending block;
wherein the at least one protrusion is slidably latched with the at least one latching portion, the retaining member passes the slot to latch on the main body, and the at least one extending block engages into the at least one opening.

2. The battery cover assembly as claimed in claim 1, wherein the at least one latching portion defines a notch and has a stopping block positioned at a corner of the notch.

3. The battery cover assembly as claimed in claim 2, wherein the notch is surrounded by a first resisting wall and a second resisting wall substantially perpendicular to the first resisting wall, and the second resisting wall defines a containing slot communicating with the notch.

4. The battery cover assembly as claimed in claim 3, wherein a resisting portion is perpendicularly extends from the second resisting wall toward the first resisting wall.

5. The battery cover assembly as claimed in claim 4, wherein the resisting portion is made of resilient material.

6. The battery cover assembly as claimed in claim 4, wherein a receiving cavity is defined between the stopping block and the second resisting wall.

7. The battery cover assembly as claimed in claim 6, wherein the protrusion comprises a base portion and a latching projection perpendicularly protruding from a side of the base portion, the base portion slidably engage in the receiving cavity, and the latching projection slidably engage in the containing slot.

8. The battery cover assembly as claimed in claim 1, wherein two opposite projections are defined on an inner surface of the main body, the two projections are spaced by the slot.

9. The battery cover assembly as claimed in claim 8, wherein the retaining member comprises a guiding portion and two extending portions, each extending portion extends from an end of the guiding portion, and a junction is formed between each extending portion and the guiding portion, each projection is blocked between the junction and the extending portion.

10. The battery cover assembly as claimed in claim 9, wherein each end of the retaining member defines a guiding surface adjacent to the junction.

11. The battery cover assembly as claimed in claim 1, wherein the retaining member is made of rubber or plastic.

12. An electronic device comprising:
a main body; and
a battery cover detachably attached to the main body, the battery cover comprises a main portion, two opposite side plates extending from lateral edges of the main portion, and an end plate extending from a top edge of the main portion to connect the two opposite side plates;
wherein at least one protrusion located on each side plate is slidably latched with the main body, at least one extending block and a retaining member for engaging with the main body are formed on the end plate, the retaining member comprises a guiding portion and two extending portions connected to the end plate, each extending portion extends from an end of the guiding portion, and a junction is formed between each extending portion and the guiding portion.

13. The electronic device as claimed in claim 12, wherein the main body comprises a sidewall defining at least one latching portion, the at least one protrusion is slidably latched with the at least one latching portion.

14. The electronic device as claimed in claim 13, wherein one end portion of the main body defines a slot, the retaining member passes the slot to latch on the main body.

15. The electronic device as claimed in claim 14, wherein the protrusion comprises a base portion and has a latching projection perpendicularly protruding from an edge of the base portion, the base portion is located on the side plate.

16. The electronic device as claimed in claim 15, wherein the at least one latching portion defines a notch and a stopping block positioned at a corner of the notch; the notch is surrounded by a first resisting wall and a second resisting wall substantially perpendicular to the first resisting wall, and the second resisting wall defines a containing slot communicating with the notch.

17. The electronic device as claimed in claim 16, wherein the latching projection slidably engage in the containing slot.

18. The electronic device as claimed in claim 14, wherein two projections opposite to each other are defined on an inner surface of the main body, the two projections are spaced from each other by the slot.

19. The electronic device as claimed in claim 18, wherein each projection is blocked between the junction and the extending portion.

20. The electronic device as claimed in claim 19, wherein each end of the retaining member defines a guiding surface adjacent to the junction.
